(19) United States
(12) Patent Application Publication
(10) Pub. No.: US 2011/0284980 A1
(43) Pub. Date: Nov. 24, 2011

(54) SOLID-STATE IMAGING DEVICE

(75) Inventors: Hiroshi Sakoh, Kyoto (JP); Masao KATAOKA, Osaka (JP); Motonari KATSUNO, Kyoto (JP); Masayuki TAKASE, Osaka (JP); Jun HIRAI, Nara (JP)

(73) Assignee: PANASONIC CORPORATION, Osaka (JP)

(21) Appl. No.: 13/106,244

(22) Filed: May 12, 2011

(30) Foreign Application Priority Data
May 18, 2010 (JP) 2010-114806

(51) Int. Cl. H01L 31/0232

(52) U.S. Cl. 257/432; 257/E31.127

(57) ABSTRACT

A solid-state imaging device according to an aspect of the present invention includes: a first photodiode and a second photodiode; a first optical waveguide formed above the first photodiode; a second optical waveguide formed above the second photodiode; a first color filter which is formed above the first optical waveguide and transmits mainly light having a first wavelength; a second color filter which is formed above the second optical waveguide and transmits mainly light having a second wavelength; a first microlens formed above the first color filter; and a second microlens formed above the second color filter, wherein the first wavelength is longer than the second wavelength, and the first optical waveguide has a first width smaller than a second width of the second optical waveguide, the first and second widths being in a direction parallel to the semiconductor substrate.

### BACKGROUND OF THE INVENTION

(1) Field of the Invention

The present invention relates to a solid-state imaging device including an optical waveguide.

(2) Description of the Related Art

Along with downsizing of cameras and an increase of the number of pixels, miniaturization of cells in solid-state imaging devices has been advanced. As a result, it has become necessary to establish a technique of preventing reduction in photosensitivity that is a key characteristic of the solid-state imaging devices.

Moreover, the advancement of the miniaturization of the cells has made it difficult to manage both the miniaturization of the cells and an increase in sensitivity, using a conventional structure. To advance the miniaturization of the cells and maintain the photosensitivity, it is essential to decrease a distance from a photodiode to the bottom of a microlens. However, especially in a MOS (Metal Oxide Semiconductor) image sensor, a line needs to be formed beside a photodiode. For this reason, the MOS image sensor has difficulty decreasing the distance from the photodiode to the bottom of the microlens. In addition, film thinning of color filters is approaching its limit.

In such a situation, required is a method for guiding, to a photodiode, light focused by a microlens, without loss. The use of a waveguide structure is known as such a method.

For instance, in a solid-state imaging device disclosed by Patent Reference 1 (Japanese Unexamined Patent Application Publication No. 2008-166677), a photodiode is formed on a surface of a semiconductor substrate, and an insulating film such as oxide silicon is formed to cover an upper layer of the semiconductor substrate and the photodiode. In addition, an insulating film is formed outside a photodiode region so that incidence of light to the photodiode is not disturbed. Moreover, in the solid-state imaging device disclosed by Patent Reference 1, an optical waveguide which waveguides, to the photodiode, light incident from outside is provided above the photodiode.

### SUMMARY OF THE INVENTION

However, in the solid-state imaging device in which the optical waveguide which waveguides, to the photodiode, the light incident on the microlens is thus provided, a problem occurs that the light in the optical waveguide leaks into a side of the insulating film.

In particular, it is prominent that light having the wavelength of 570 nm or more leaks into the side of the insulating film. More specifically, red light leaks into the side of the insulating film when a primary color filter is used, and yellow light and magenta light leak into the side of the insulating film when a complementary color filter is used.

Consequently, a conventional solid-state imaging device has a problem that color mixing to adjacent pixels occurs, which results in deterioration of color reproducibility.

Therefore, the present invention has an object to provide a solid-state imaging device which is capable of enhancing color reproducibility.

In order to achieve the above object, a solid-state imaging device according to an aspect of the present invention is a solid-state imaging device including: a semiconductor substrate; a first photodiode and a second photodiode which are formed in the semiconductor substrate; an interlayer insulating film formed on the semiconductor substrate; a first optical waveguide which is formed in the interlayer insulating film above the first photodiode and has a refractive index higher than a refractive index of the interlayer insulating film; a second optical waveguide which is formed in the interlayer insulating film above the second photodiode and has a refractive index higher than the refractive index of the interlayer insulating film; a first color filter which is formed above the first optical waveguide and transmits mainly light having a first wavelength; a second color filter which is formed above the second optical waveguide and transmits mainly light having a second wavelength; a first microlens formed above the first color filter; and a second microlens formed above the second color filter, wherein the first wavelength is longer than the second wavelength, and the first optical waveguide has a first width smaller than a second width of the second optical waveguide, the first and second widths being in a direction parallel to the semiconductor substrate.

With this configuration, in the solid-state imaging device according to the aspect of the present invention, the width of the first optical waveguide formed above the first photodiode which receives light having a long wavelength is smaller than the width of the second optical waveguide formed above the second photodiode which receives light having a short wavelength. This successfully increases a distance between the first optical waveguide and other optical waveguides adjacent to the first optical waveguide, and thus it is possible to suppress leakage of the light having the long wavelength in the optical waveguide into adjacent pixels. With this, the solid-state imaging device according to the aspect of the present invention makes it possible to reduce color mixing to the adjacent pixels, thereby enhancing color reproducibility.

Moreover, the light having the first wavelength may be red, and the light having the second wavelength may be green or blue.

With this configuration, the solid-state imaging device according to the aspect of the present invention makes it possible to suppress leakage of the red light in the optical waveguide into an adjacent pixel which receives the green light or into an adjacent pixel which receives the blue light.

Furthermore, the light having the first wavelength may be magenta or yellow, and the light having the second wavelength may be cyan or green.

With this configuration, the solid-state imaging device according to the aspect of the present invention makes it possible to suppress leakage of the magenta or yellow light in the optical waveguide into an adjacent pixel which receives the cyan light or into an adjacent pixel which receives the green light.

Moreover, the first optical waveguide may have a width of 700 nm to 900 nm in the direction parallel to the semiconductor substrate, and the second optical waveguide may have a width of 900 nm to 1000 nm in the direction parallel to the optical waveguide.

Furthermore, the first and second optical waveguides may have a depth of 1300 nm to 1600 nm in a direction perpendicular to the semiconductor substrate.

It is to be noted that the present invention can be implemented not only as such a solid-state imaging device but also as a method of manufacturing the same.

Further, the present invention can be implemented as a semiconductor integrated circuit (LSI) achieving part or all of functions of the solid-state imaging device and as a camera including the solid-state imaging device.

Therefore, the present invention can provide the solid-state imaging device which is capable of enhancing the color reproducibility.

### FURTHER INFORMATION ABOUT TECHNICAL BACKGROUND TO THIS APPLICATION

The disclosure of Japanese Patent Application No. 2010-114806 filed on May 18, 2010 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 is a cross-sectional view of a solid-state imaging device according to Embodiment 1 of the present invention;

FIG. 2 is a diagram showing spectral sensitivity characteristics of the solid-state imaging device according to Embodiment 1 of the present invention;

FIG. 3 is an enlarged view of one of the spectral sensitivity characteristics of the solid-state imaging device according to Embodiment 1 of the present invention;

FIG. 4 is an enlarged view of two of the spectral sensitivity characteristics of the solid-state imaging device according to Embodiment 1 of the present invention;

FIG. 5 is an enlarged view of two of the spectral sensitivity characteristics of the solid-state imaging device according to Embodiment 1 of the present invention;

FIG. 6 is an enlarged view of one of the spectral sensitivity characteristics of the solid-state imaging device according to Embodiment 1 of the present invention;

FIG. 7 is a cross-sectional view of a comparative example of the solid-state imaging device according to Embodiment 1 of the present invention;

FIG. 8 is a cross-sectional view of the solid-state imaging device according to Embodiment 1 of the present invention;

FIG. 9 is a diagram showing spectral sensitivity characteristics of the solid-state imaging device according to Embodiment 1 of the present invention;

FIG. 10 is a diagram showing spectral sensitivity characteristics of the solid-state imaging device according to Embodiment 1 of the present invention; and

FIG. 11 is a cross-sectional view of the solid-state imaging device according to Embodiment 2 of the present invention.

### DESCRIPTION OF THE PREFERRED EMBODIMENT(S)

The following describes a solid-state imaging device according to embodiments of the present invention with reference to the drawings.

### Embodiment 1

In a solid-state imaging device 100 according to Embodiment 1 of the present invention, a width of an optical waveguide formed above a photodiode which receives red light is smaller than a width of an optical waveguide formed above a photodiode which receives blue light and a width of an optical waveguide formed above a photodiode which receives green light. This successfully increases a distance between the optical waveguide formed above the photodiode which receives red light and the other optical waveguides adjacent to the optical waveguide, and thus it is possible to suppress leakage of the red light in the optical waveguide into adjacent pixels. With this, the solid-state imaging device 100 according to Embodiment 1 of the present invention makes it possible to reduce color mixing to the adjacent pixels, thereby enhancing color reproducibility.

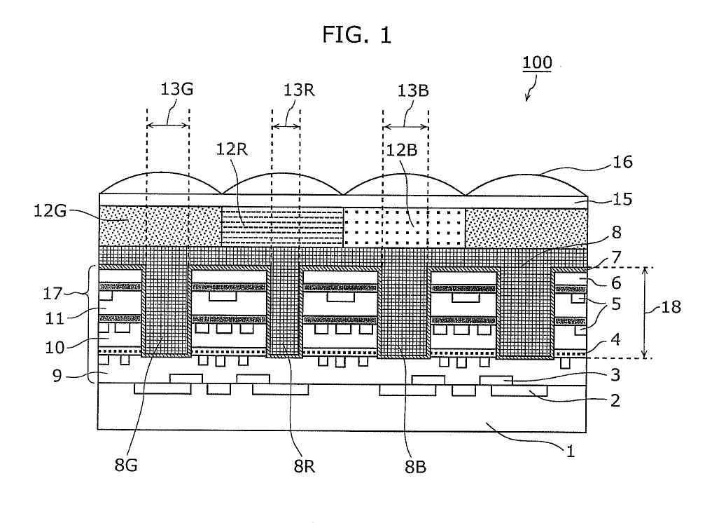

The following first describes a structure of the solid-state imaging device 100 according to Embodiment 1 of the present invention. FIG. 1 is a cross-sectional view showing the structure of the solid-state imaging device 100 according to Embodiment 1 of the present invention.

The solid-state imaging device 100 shown in FIG. 1 is a MOS solid-state imaging device (MOS image sensor) having a waveguide structure to which primary color filters are applied. The solid-state imaging device 100 includes a semiconductor substrate 1, a photodiode 2, a transfer gate 3, an interlayer insulating film 17, a high-refractive film 8, color filters 12R, 12G, and 12B, a planarizing film 15, and a microlens 16.

The semiconductor substrate 1 is, for example, a silicon substrate. The photodiode 2 is formed for each pixel in a pixel region of the semiconductor substrate 1 which is a light-receiving surface. The photodiode 2 generates signal charges by photoelectrically converting incident light, and accumulates the generated signal charges.

The transfer gate 3 is formed on a surface of the semiconductor substrate 1, and is used for reading the signal charges accumulated in the photodiode 2.

The interlayer insulating film 17 is formed on the semiconductor substrate 1 to cover the photodiode 2 and the transfer gate 3. A recess is formed at an upper portion of each photodiode 2 in the interlayer insulating film 17. The interlayer insulating film 17 includes a diffusion barrier film 4, a line 5, insulating films 6, 9, 10, and 11, and a protective film 7 that are stacked.

The protective film 7 is formed to cover the interlayer insulating film 17 and an inside wall of the recess formed in the interlayer insulating film 17.

The high-refractive film 8 is formed on the protective film 7. Moreover, the high-refractive film 8 has a refractive index higher than that of the interlayer insulating film 17 (insulating films 6, 9, 10, and 11). For instance, refractive index n of the high-refractive film 8 is between 1.6 and 1.9 inclusive. The high-refractive film 8 serves as an optical waveguide which guides the incident light to the photodiode 2.

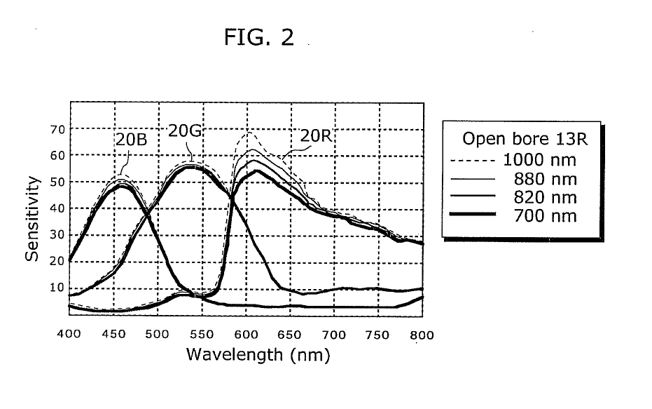

The color filters 12R, 12G, 12B are formed above the interlayer insulating film 17. The color filter 12R transmits red light, the color filter 12G transmits green light, and the color filter 12B transmits blue light. It is to be noted that, for instance, transmitting the red light means transmitting mainly light having a red wavelength band and blocking light having a wavelength band other than the red wavelength band. To be exact, as in a spectral sensitivity characteristic to be described shown in FIG. 2, the filter which transmits the red light is a filter having a peak transmittance in the red wavelength band.

The planarizing film 15 is formed on the color filters 12R, 12G, and 12B. The microlens 16 is formed on the planarizing film 15 for each of the color filters 12R, 12G, and 12B.

Moreover, each recess formed in the interlayer insulating film 17 has a different open bore depending on a corresponding one of the color filters 12R, 12G, and 12B formed thereon. More specifically, an open bore 13R (width in a direction parallel to the semiconductor substrate 1 (transverse direction in FIG. 1)) of an optical waveguide 8R formed below the color filter 12R is smaller than an open bore 13G of an optical waveguide 8G formed below the color filter 12G and an open bore 13B of an optical waveguide 8B formed below the color filter 12B.

For example, in the case of a cell having the size of 1.4 μm, the open bore 13R is between 700 nm and 900 nm inclusive in size. The open bores 13G and 13B are between 900 nm and 1000 nm inclusive in size. A depth 18 of the recess formed in the interlayer insulating film 17 is between 1300 nm and 1600 nm inclusive. Moreover, for instance, each pixel cell of a corresponding one of colors has the same size.

The high-refractive film 8 is formed not only in the optical waveguide but also above a mouth of an opening from 0 nm up to 1000 nm.

The color filters 12R, 12G, and 12B have the thickness of 300 nm to 1000 nm, the planarizing film 15 has the thickness of 10 nm to 500 nm, and the microlens 16 has the height of 100 to 1000 nm.

The following describes spectral sensitivity characteristics of the solid-state imaging device 100. FIG. 2 is a diagram showing a spectral sensitivity characteristic 20R of the photodiode 2 formed below the color filter 12R, a spectral sensitivity characteristic 20G of the photodiode 2 formed below the color filter 12G, and a spectral sensitivity characteristic 20B of the photodiode 2 formed below the color filter 12B, when the open bore 13R is 700 nm, 820 nm, 880 nm, or 1000 nm in size and when the open bores 13G and 13B are 1000 nm in size.

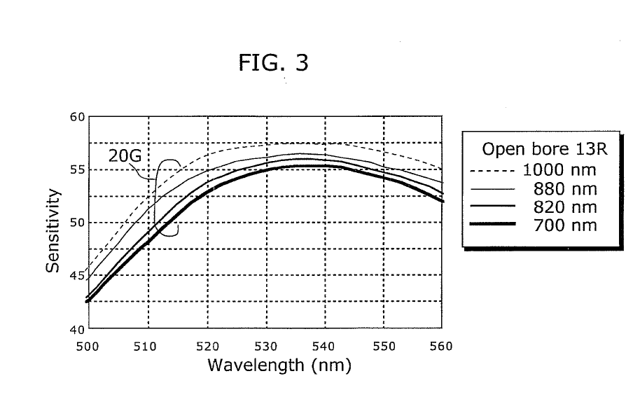

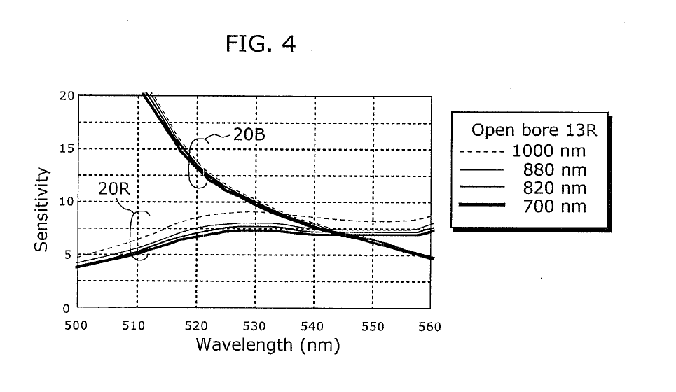

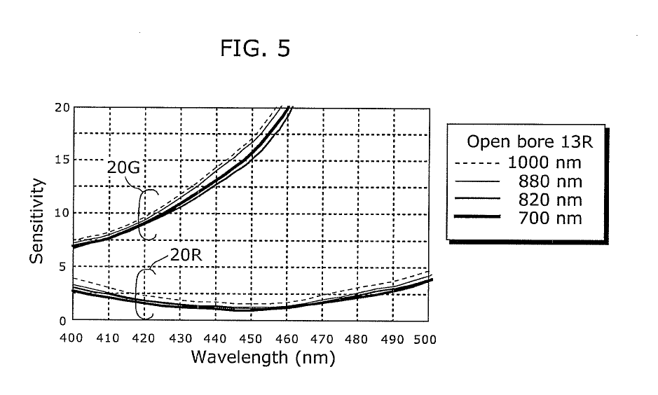

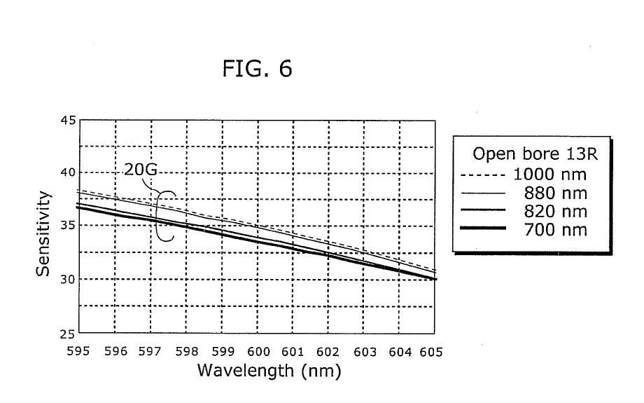

FIG. 3 is an enlarged view of the spectral sensitivity characteristic 20G in the vicinity of the sensitivity peak (in the vicinity of 530 nm) of green (the spectral sensitivity characteristic 20G) shown in FIG. 2. FIG. 4 is an enlarged view of the spectral sensitivity characteristics 20R and 20B in the vicinity of the sensitivity peak (in the vicinity of 530 nm) of the green. FIG. 5 is an enlarged view of the spectral sensitivity characteristics 20R and 20G in the vicinity of the sensitivity peak (in the vicinity of 460 nm) of blue (the spectral sensitivity characteristic 20B). FIG. 6 is an enlarged view of the spectral sensitivity characteristic 20G in the vicinity of the sensitivity peak (in the vicinity of 600 nm) of red (the spectral sensitivity characteristic 20R).

As shown in FIGS. 3 to 5, the spectral sensitivity characteristic 20R of the red shows that the spectral sensitivity reduces in the vicinity of the sensitivity peak of the green (525 nm) and of the sensitivity peak of the blue (460 nm) as the open bore 13R becomes smaller. Similar to the spectral sensitivity characteristic 20R of the red, the spectral sensitivity characteristic 20G of the green and the spectral sensitivity characteristic 20B of the blue also show that the spectral sensitivity reduces in the vicinity of the sensitivity peak of the green (525 nm) and of the sensitivity peak of the blue (460 nm) as the open bore 13R becomes smaller.

As shown in FIG. 6, the spectral sensitivity characteristic 20G of the green also shows that the spectral sensitivity reduces in the vicinity of the spectral sensitivity peak of the red (in the vicinity of 600 nm) as the open bore 13R becomes smaller.

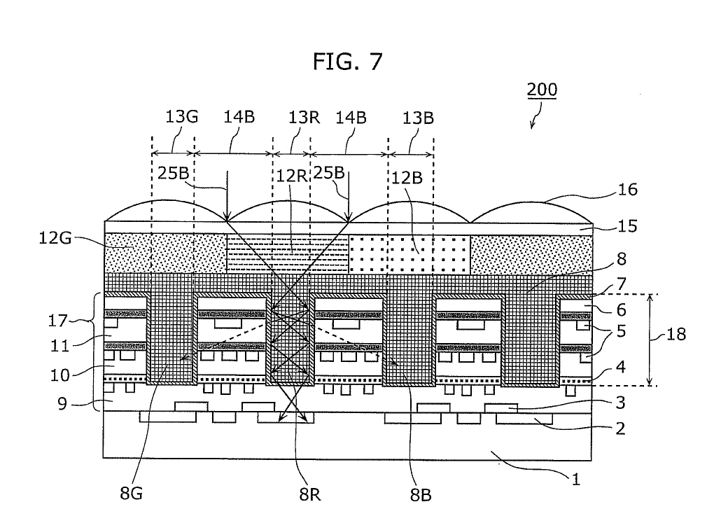

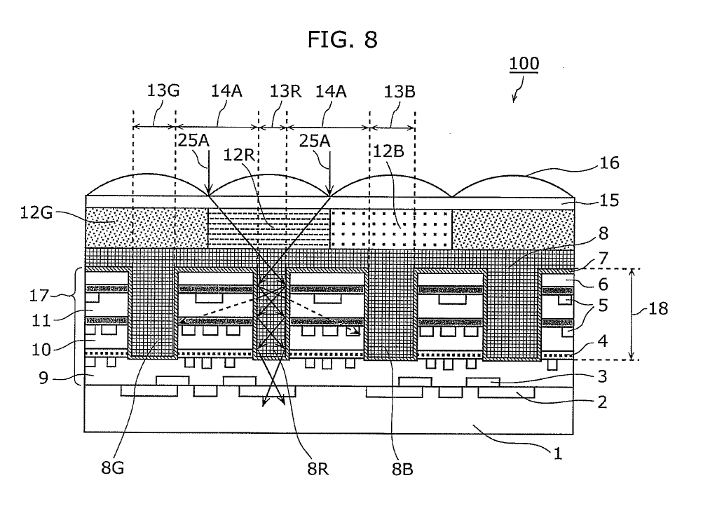

FIG. 7 is a diagram for comparison, and is a diagram showing a state of incident light 25B in a solid-state imaging device 200 in which the optical waveguide 8R has the open bore 13R that is the same as the open bore 13B of the optical waveguide 8B and the open bore 13G of the optical waveguide 8G. FIG. 8 is a diagram showing a state of incident light 25A in the solid-state imaging device 100 according to Embodiment 1 of the present invention.

As shown in FIG. 7, when the open bore 13R is large, the incident light 25B in the optical waveguide 8R leaks through walls of the optical waveguide into adjacent pixels. In contrast, as shown in FIG. 8, when the open bore 13R is small, a distance 14A from the optical waveguide 8R to the optical waveguide 8G or 8B of an adjacent pixel (e.g., 450 nm to 550 nm) is longer than a distance 14B from the optical waveguide 8R to the optical waveguide 8G or 8B of the adjacent pixel in the case shown in FIG. 7. As stated above, decreasing the open bore 13R reduces an amount of leakage from the optical waveguide 8R into the optical waveguide 8G or 8B. Thus, color mixing is reduced.

The following describes, for comparison, a change of spectral sensitivity when the open bore 13B of the optical waveguide 8B and the open bore 13G of the optical waveguide 8G are changed.

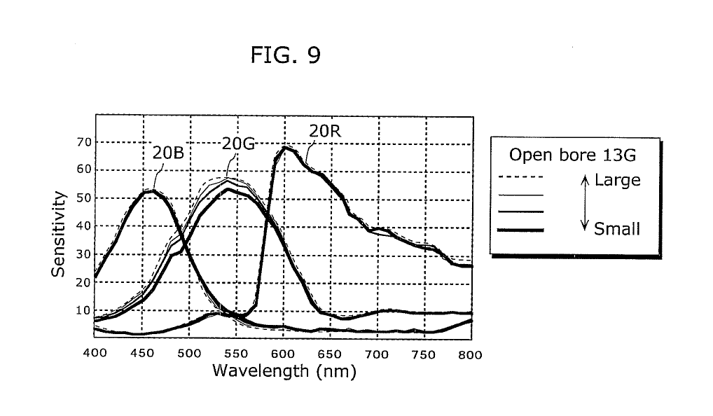

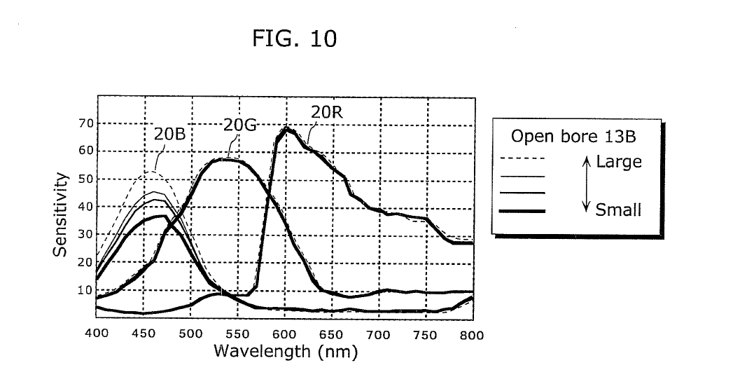

FIG. 9 is a diagram showing spectral sensitivity characteristics when the open bore 13G of the optical waveguide 8G of the green is changed. FIG. 10 is a diagram showing spectral sensitivity characteristics when the open bore 13B of the optical waveguide 8B of the blue is changed.

As shown in FIG. 9, when the open bore 13G of the green is changed, the spectral sensitivity characteristic 20G of the green changes, but the spectral sensitivity characteristic 20R of the red and the spectral sensitivity characteristic 20B of the blue barely change in many wavelength bands. It is to be noted that the spectral sensitivity characteristic 20R of the red and the spectral sensitivity characteristic 20B of the blue are affected by the change of the open bore 13G of the green in the vicinity of the sensitivity peak of the green (in the vicinity of 530 nm).

Furthermore, as shown in FIG. 10, when the open bore 13B of the optical waveguide 8B of the blue is changed, the spectral sensitivity characteristic 20B of the blue changes, but it is clear that the spectral sensitivity characteristic 20R of the red and the spectral sensitivity characteristic 20G of the green are not affected in any wavelength band by the change of the open bore 13B.

As stated above, it is clear that the longer a wavelength is, the more greatly other color pixels are affected by a change of an open bore. In particular, the other color pixels are most greatly affected by the open bore 13R of the red having the longest wavelength.

It is to be noted that conceivable is a method of decreasing the open bore 13G of the green and the open bore 13B of the blue by increasing the open bore 13R of the red. However, it is necessary to set the sensitivity of the green as high as possible. Moreover, the larger an open bore of the optical waveguide is, the more the sensitivity is enhanced. Consequently, it is not desirable to decrease the open bore 13G of the green. In other words, as a method of reducing color mixing, it is desirable to decrease the open bore 13R of the red.

Furthermore, while it is possible to reduce the color mixing more as the open bore 13R of the red is smaller, the sensitivity of the red is reduced. As a result, a cross-point between the spectral sensitivity characteristic 20R of the red and the spectral sensitivity characteristic 20G of the green becomes higher, and color separation deteriorates. For this reason, setting an open bore also requires a standard. As an example, there is a method in which a difference between the peak of the red and the cross-point is predetermined, and an open bore which satisfies the difference is set.

### Embodiment 2

In Embodiment 2, described is a modification of the solid-state imaging device 100 according to Embodiment 1, that is, a solid-state imaging device 100A to which complementary color filters are applied.

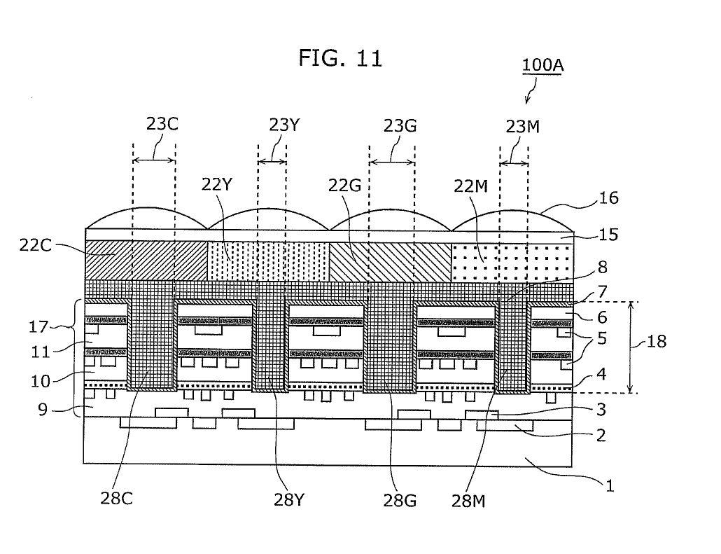

FIG. 11 is a cross-sectional view of the solid-state imaging device 100A according to Embodiment 2 of the present invention. It is to be noted that the same reference signs are assigned to the same elements as in FIG. 1, and an overlapping description is omitted.

In comparison with the solid-state imaging device 100 shown in FIG. 1, the solid-state imaging device 100A shown in FIG. 11 includes color filters 22C, 22Y, 22G, and 22M instead of the color filters 12R, 12G, and 12B.

The color filters 22C, 22Y, 22G, and 22M are formed above the interlayer insulating film 17. The color filter 22C transmits cyan light, the color filter 22Y transmits yellow light, the color filter 22G transmits green light, and the color filter 22M transmits magenta light.

Moreover, an open bore 23Y of an optical waveguide 28Y formed below the color filter 22Y and an open bore 23M of an optical waveguide 28M formed below the color filter 22M are smaller than an open bore 23C of an optical waveguide 28C formed below the color filter 22C and an open bore 23G of an optical waveguide 28G formed below the color filter 22G.

More specifically, in the case of a cell having the size of 1.4 μm, the open bores 23Y and 23M are between 700 nm and 900 nm inclusive in size. In addition, in the case of the cell having the size of 1.4 μm, the open bores 23C and 23G are between 900 nm and 1000 nm inclusive in size. A depth 18 of a recess formed in the interlayer insulating film 17 is between 1300 nm and 1600 nm inclusive.

Therefore, like the solid-state imaging device 100 according to Embodiment 1, the solid-state imaging device 100A according to Embodiment 2 of the present invention makes it possible to suppress leakage of the yellow light and magenta light into adjacent pixels in the optical waveguides. With this, the solid-state imaging device 100A makes it possible to reduce color mixing to the adjacent pixels, thereby enhancing color reproducibility.

Furthermore, the solid-state imaging device according to each of Embodiments 1 and 2 is implemented as an LSI which is an integrated circuit.

Moreover, although corners and sides of each element are illustrated by straight lines in each drawing, the present invention includes rounded corners and sides due to manufacturing reasons.

Furthermore, at least some of functions of the solid-state imaging device according to each of Embodiments 1 and 2 and the modification thereof may be combined.

Moreover, although Embodiments 1 and 2 have described the example where the present invention is applied to the MOS solid-state imaging device, the present invention may be applied to a CCD (Charge Coupled Device) solid-state imaging device.

Furthermore, the present invention may be implemented as a camera including the solid-state imaging device. Moreover, the above numbers are used for specifically describing the present invention, and the present invention is not limited to the numbers. Furthermore, the material of each element is shown above for specifically describing the present invention, and the present invention is not limited to the materials.

Those skilled in the art will readily appreciate that many modifications are possible in the embodiments without materially departing from the novel teachings and advantages of the present invention. Accordingly, all such modifications are intended to be included within the scope of the present invention.

### INDUSTRIAL APPLICABILITY

The present invention is applicable to solid-state imaging devices. In addition, the present invention is applicable to cameras including a solid-state imaging device such as MOS cameras.

What is claimed is:

1. A solid-state imaging device comprising:
a semiconductor substrate;
a first photodiode and a second photodiode which are formed in said semiconductor substrate;
an interlayer insulating film formed on said semiconductor substrate;
a first optical waveguide which is formed in said interlayer insulating film above said first photodiode and has a refractive index higher than a refractive index of said interlayer insulating film;
a second optical waveguide which is formed in said interlayer insulating film above said second photodiode and has a refractive index higher than the refractive index of said interlayer insulating film;
a first color filter which is formed above said first optical waveguide and transmits mainly light having a first wavelength;
a second color filter which is formed above said second optical waveguide and transmits mainly light having a second wavelength;
a first microlens formed above said first color filter; and
a second microlens formed above said second color filter,
wherein the first wavelength is longer than the second wavelength, and said first optical waveguide has a first width smaller than a second width of said second optical waveguide, the first and second widths being in a direction parallel to said semiconductor substrate.

2. The solid-state imaging device according to claim 1,
wherein the light having the first wavelength is red, and the light having the second wavelength is green or blue.

3. The solid-state imaging device according to claim 1,
wherein the light having the first wavelength is magenta or yellow, and the light having the second wavelength is cyan or green.

4. The solid-state imaging device according to claim 1,
wherein said first optical waveguide has a width of 700 nm to 900 nm in the direction parallel to said semiconductor substrate, and said second optical waveguide has a width of 900 nm to 1000 nm in the direction parallel to said optical waveguide.

5. The solid-state imaging device according to claim 1,
wherein said first and second optical waveguides have a depth of 1300 nm to 1600 nm in a direction perpendicular to said semiconductor substrate.
